(19) United States
(12) Patent Application Publication
(10) Pub. No.: US 2008/0106146 A1
(43) Pub. Date: May 8, 2008

(54) Management System for In-House Power Quantity Consumed

(75) Inventors: Seung-Myun Baek, Kyungsangnam-Do (KR); Koon Seok Lee, Kyungsangnam-Do (KR)

Correspondence Address: MCKENNA LONG & ALDRIDGE LLP, 1900 K STREET, NW, WASHINGTON, DC, 20006, US

(73) Assignee: LG Electronics Inc., Seoul, (KR)

(21) Appl. No.: 11/666,676

(22) PCT Filed: Nov. 2, 2004
(86) PCT No.: PCT/KR04/02797

§ 371 Date: Nov. 28, 2007

(51) Int. Cl. H02J 3/14; G01R 21/00; G05F 1/66

(52) U.S. Cl. 307/35; 702/62; 700/291

(57) ABSTRACT

The present invention relates to a management system for in-house power consumption, more particularly to a management system for in-house power consumption efficiently performing in-house power consumption by means of estimating power consumption of each operation of in-house electric devices. The present invention provides a management system for in-house power consumption comprising: at least one or more electric devices (30, 40, 50, 60) which comprise a communication means and transmit current operation information via the communication means on a given network; an power sensor module (20) that measures an instantaneous power consumption of the total electric devices and transmit it on the network; and a power consumption controller (70) that saves a previously received the operation information and the instantaneous power consumption and estimates the power consumption of each electric device (30, 40, 50, 60) on the basis of the saved operation information and instantaneous power consumption and the currently received operation information and instantaneous power consumption.

### TECHNICAL FIELD

The present invention relates to a management system for in-house power consumption, more particularly to a management system for in-house power consumption efficiently performing in-house power consumption by means of estimating power consumption of each operation of in-house electric devices.

### BACKGROUND ART

The general composition of a in-house power management system is illustrated in FIG. 1.

As shown in the figure, the in-house power management system is consisted of a wattmeter 1 that is connected to an in-house power line through which electric power is transmitted into the house 10, and electric devices such as a washing machine 2, an air-conditioner 3, a microwave oven 4 and an electric iron 5 which are connected to the wattmeter 1 and supplied with in-house 10 electric power and perform their specific functions.

More particularly, the wattmeter 1 generally measures power consumption of in-house 10 electric devices 2, 3, 4, 5 (generally, accumulated electric power consumption). An electric power company estimates a power rate of power consumption according to the measured in-house power consumption.

In addition, the wattmeter 1 is able to turn on or turn off power of in-house electric devices 2, 3, 4, 5 at the same time by controlling an inflow of in-house 10 power.

Here, the washing machine 2, air-conditioner 3, microwave oven 4 and the electric irons 5 were referred as examples of the in-house electric devices that harness electricity. Therefore, electric devices of this invention include all kinds of electric devices operated by electricity.

According to a prior art, although a user could confirm total accumulated power consumption of all the electric devices 2, 3, 4, 5, it has not been possible to identify real-time power consumption of each in-house electric devices 2, 3, 4, 5. In addition, a user could not find the power rate of electric power consumption for a certain period of time.

Furthermore, according to the prior art, a user can watch the operation of each electric devices with its own eyes, however it was not possible to confirm the power consumption by the operation.

In addition, according to the prior art, a user should use and/or control the in-house electric devices by oneself in order to reduce power consumption or to use them efficiently.

### DISCLOSURE OF THE INVENTION

The present invention is accomplished to solve the problems of the prior art and the object of the present invention is to provide a management system for in-house power consumption that can estimate power consumption of each in-house electric devices and power consumption according to individual function modules of the electric devices

Another object of the present invention is to provide a management system for in-house power consumption that can provide a user with various methods to control in-house power in accordance with operation information, power consumption and/or a power rate of in-house electric devices.

Another object of the present invention is to provide a management system for in-house power consumption that can control the in-house electric devices with the power management method set by a user or set automatically in according to operation information, each power consumption and/or power rates of in-house electric devices.

Another object of the present invention is to provide a management system for in-house power consumption that can control the operation of each electric device in accordance with internal or external environment of each house so that it can achieve efficient power consumption.

Another object of the present invention is to provide a management system for in-house power consumption that can control individual function modules of the electric devices in order to control power to be efficiently consumed.

Another object of the present invention is to provide a management system for in-house power consumption enabling a user to identify the condition of each electric devices and/or the individual function module thereof by means of power consumption of each electric devices and/or power consumption according to the individual function module of each electric devices.

In order to achieve such objects, the present invention provides a management system for in-house power consumption comprising: at least one or more electric devices which comprise a communication means and transmit current operation information via the communication means on a given network; an power sensor module that measures an instantaneous power consumption of the total electric devices and transmit it on the network; and a power consumption controller that saves a previously received the operation information and the instantaneous power consumption and estimates the power consumption of each electric device on the basis of the saved operation information and instantaneous power consumption and the currently received operation information and instantaneous power consumption.

Preferably, the operation information includes currently operating individual function modules of the electric devices.

Preferably, the electric devices transmit the operation information to the power consumption controller whenever there is a change of its operation.

Preferably, the power consumption controller estimates power consumption of each of the currently operating individual function modules of the electric devices and then estimates the power consumption of the electric devices according to the estimated power consumption of the individual function modules.

Preferably, the power consumption controller provides a user with at least of one or more information among the operation information, power consumption of the electric devices and power consumption of each function module of the electric devices.

Preferably, the system further comprises an electric device which does not comprise a communication means and the second power sensor module which is connected between the electric device and the network and transmits the instantaneous power consumption of the electric devices to the power consumption controller.

Preferably, the power sensor module is consisted of a power measuring means that measures the instantaneous power consumption and a transmission means that transmits the measured instantaneous power consumption to the power consumption controller.

Preferably, the power consumption controller estimates a power rate based on accumulated consumption of the electric devices for the certain period of time and provides it to a user.

Preferably, the power consumption controller provides the user with the most appropriate method for utilizing the electric devices based on the estimated power rate.

Preferably, the most appropriate method for utilizing the electric devices comprises a method of use of individual function module of the electric devices.

Preferably, the most appropriate method for utilizing the electric devices includes the operating time of the electric devices.

Preferably, the system further comprises an indoor environment sensor and outdoor environment sensor to collect environmental information of an place where the sensors are installed and the power consumption controller individually control the electric devices according to the environmental information received from the indoor environment sensor and outdoor environment sensor.

Preferably, the power consumption controller controls air-conditioning function module not to be over-operated among the function modules of the electric devices.

In addition, the present invention provides a management system for in-house power consumption comprising: at least one or more electric devices which comprise a communication means and transmits current operation information via the communication means on a given network; an power sensor module that measures an instantaneous power consumption of the total electric devices and transmits it through the network, and a power consumption controller that receives the operation information and the instantaneous power consumption and estimates accumulated power consumption of electric devices for a certain period of time and provides a user with the accumulated power consumption a nd the operation information of the electric devices.

Preferably, the power consumption controller performs a power management method when the accumulated power consumption is higher than the predetermined peak value of supply power.

Preferably, the power consumption controller stops the whole function or a part of the function of the electric devices by the power management method.

Preferably, the power consumption controller stops the whole function or a part of the function of the electric devices according to a predetermined priority in performing the power management method.

Preferably, the operation information includes currently operating individual function modules of the electric devices.

Preferably, the power consumption controller stops individual function module of the electric devices.

Preferably, wherein, the power consumption controller estimates a power rate with the accumulated power consumption.

Preferably, the power consumption controller provides a message of restriction of use of the electric devices to the user when the power rate is more than the predetermined peak value of a power rate.

### BRIEF DESCRIPTION OF THE DRAWINGS

The characteristics and advantages of the present invention can be better understood the attached figures along with along with detailed description of the invention which follows afterwards.

FIG. 1 is a block diagram of a conventional in-house power management system.

FIG. 2 is a block diagram of a management system of in-house power consumption according to the preset invention.

FIG. 3 is a block diagram of a power sensor module of FIG. 2.

FIG. 4 is an outlined block diagram of an air conditioner of FIG. 2.

FIG. 5 is a flowchart of a method to estimate power consumption of each electric device according to a management system for in-house power consumption of the present invention.

FIG. 6 is an example of a table of in-house power consumption of FIG. 5.

FIG. 7 is a flowchart of a power management method of electric power by a management system for in-house power consumption according to the present invention.

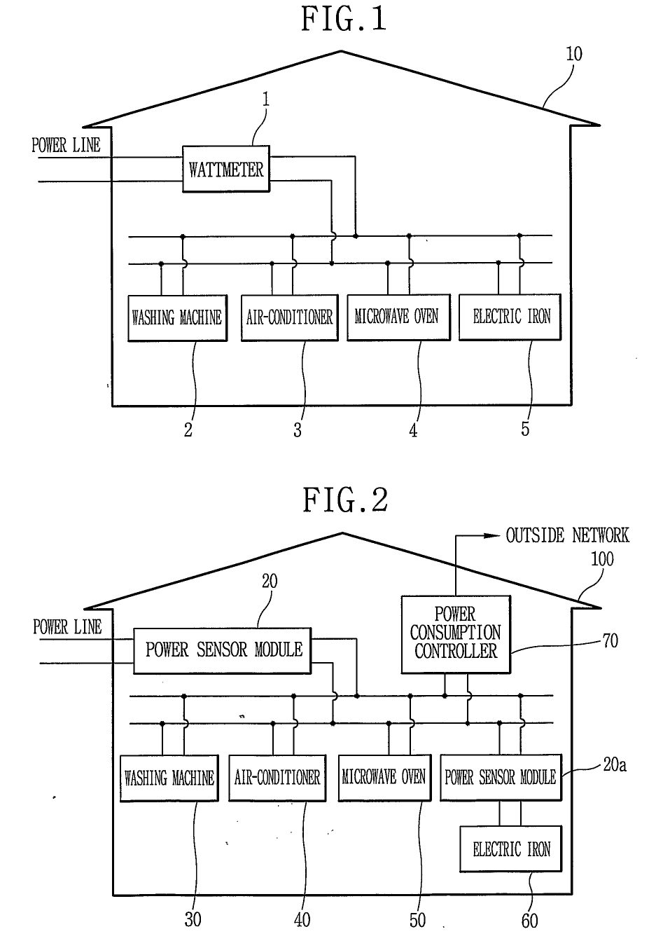

### BEST MODE FOR CARRYING OUT THE INVENTION

The preferred embodiments to realize the objects of the present invention will be described in detail hereafter, referring to the attached drawings and figures.

FIG. 2 is a block diagram of a management system for in-house power consumption according to the present invention.

Shown in the figure, the management system for in-house power consumption is consisted of a power sensor module 20 that is connected to a in-house 100 power line, measures power consumption and transmits the measured power consumption to a power consumption controller 70 through a power line; an in-house electric devices such as a washing machine 30, air-conditioner 40, microwave oven 50 and electric iron 60 which are connected with a power sensor module 20 and supplied with in-house 100 power 100 and performs specific functions and transmit a operation information including the currently operating function module to the power consumption controller 70; and a power consumption controller 70 which is connected to an in-house 100 power line and estimates power consumption of each electric devices and/or power consumption of the function modules of the electric devices based on a power consumption information received from the power sensor module 20 and the operation information received from the electric devices 30, 40, 50, 60.

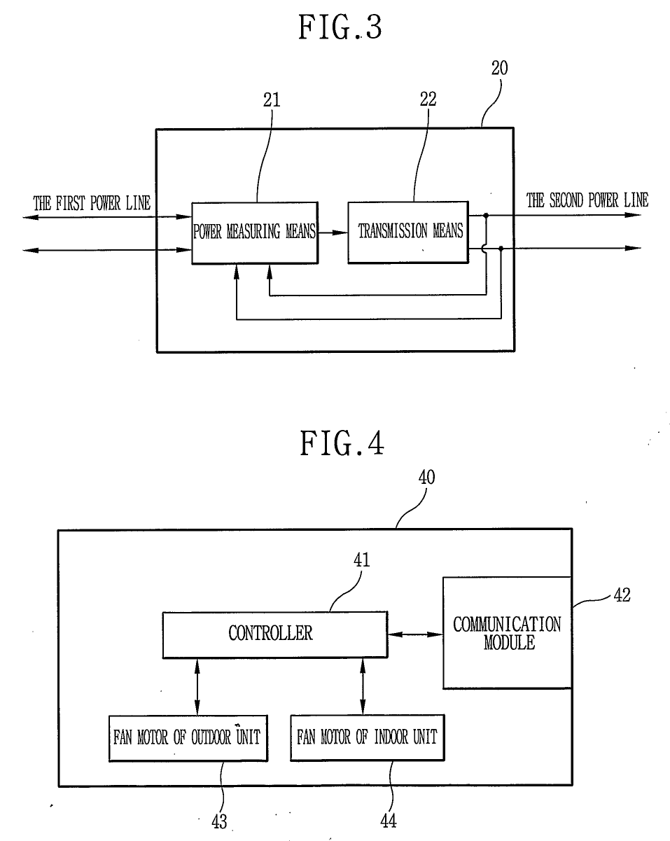

More particularly, the power sensor module 20, shown in FIG. 3, is consisted of a power measuring means 21 and a transmission means 22 to transmit the measured power consumption to the power consumption controller 70 in a form of certain data format (for example, data formed according to a LnCP protocol). The power sensor module 20 may be consisted of wattmeter 1 and a transmission means connected to the wattmeter to transmit the measured power consumption through a power line (for example, power line modems, etc.). The power sensor module 20 may utilize an installed wattmeter 1, or it can be composed of integrated unit of power measuring means 21 substituted for the wattmeter 1 of prior art, and the transmission means 22.

In addition, the transmission means 22 is applied with power and receives and transmits power consumption from the power measuring means 21 and therefore supplies power to the electric devices 30, 40, 50, 60, a power sensor module 20a and a power consumption controller 70, and transmits the power consumption to the power consumption controller 70.

In addition, an power measuring means 21 may receive power through the first power line and output it through the second power line, or receive power through the second power line and output it through the first power line. For example, if a power line which allows power to flow into the house 100 is the first power line, the power line drawn into the house 100 becomes the second power line, the electric power applied with the first power line is applied into the house 100 through the second power line. In addition, the power line to be connected to an electric iron 60 becomes the first power line and the power line in the house becomes the second power line, the power applied with the second power line is supplied to the electric iron 60 through the first power line. As this occurs, power should not pass through the transmission means 22, however power for use in operation of the transmission means 22 should be supplied to the transmission means.

Next, the electric devices such as a washing machine 30, air-conditioner 40, microwave oven 50 is connected with the power line and supplied with power and the electric devices comprises a communication module (for example, power line modem) so that it may communicate with the power consumption controller 70 through the power line.

FIG. 4 illustrates an outlined block diagram of an air-conditioner of FIG. 2 as an example of such electric devices. Shown in the figure, an air-conditioner 40 is consisted of a controller 41 to control a fanning and/or cooling cycle, a data communication module 42, which is connected to power line, to enable the communication between the controller 41 and power consumption controller 70, fan motor of outdoor unit 43 to operate of outdoor unit of air-conditioner and a fan motor of indoor unit 44 to operate indoor unit of the air-conditioner.

The fan motor of outdoor unit 43 and fan motor of indoor unit 44 of the air-conditioner may be referred as a function module here, the function module effects a certain operation and consume a certain amount of electric power. It appears that the controller 41 becomes one function module, too. Basically, the one element to carry out one function is specified as a function module. For example, if the operation of the fan motor of outdoor unit 43 is one operation, it becomes one function module. However, in case that it can operate in high speed or in low speed operation, that is consuming different quantity of power, it can be distinguished as two different function modules even though it carries out same function.

Another electric devices such as a washing machine 30 or a microwave oven 50 is distinguished as single or multiple function modules according to their function operations in the same way of the air-conditioner 40 stated above and comprise a communication module. The communication module 42 may be an interior type placed inside electric devices by a manufacturer or exterior type that connected from the outside of electric devices to electric devices through a certain terminal to make it possible to communicate.

Generally, different from a washing machine 30, air-conditioner 40 and a microwave oven 50, it is difficult for an electric iron 60 to equip with a communication means such as a communication module shown in FIG. 4, due to its small size and generation of heat. The electric devices which do not equip with communications means due to a technical or economical reasons or for enhancing convenience for a user is directly supplied with power through the power sensor module 20a, shown in FIG. 2. The power sensor module 20a measures power consumption through an power measuring means 21 by means of on/off state of an electric iron 60, and the power consumption is transmitted to the power consumption controller 70 through the transmission means 22. In other words, when the power sensor module 20a transmits electric power through a power line, the power consumption can function as operation information to show whether the electric iron 60 is turn on or off. The power consumption controller 70 detects an operation of the electric iron 60 by receiving the power consumption or quantity thereof. The power sensor module 20a has a similar composition with the power sensor module 20.

Next, the power consumption controller 70 is a kind of network controller that can communicate with electric devices 30, 40, 50 and power sensor module 20, 20a through a universal network such as a power line in order to control total power consumption in the house 100. The power consumption controller 70 may be a communication device that is built in a personal computer or a set-top box or certain electric devices (for example, a refrigerator, etc.). In addition, the power consumption controller 70 can communicate, connected to an outside network (For example, a dedicated network such as internet network)

The power consumption controller 70 is actually consisted of one or more controller, a communication interface for a power line communication (that is, an universal network communication) and a communication with an external network (that is, a dedicated network communication) and a storage means to save a received operation information and an instantaneous power consumption, the control of power is carried out with data flow between these components. However such a data flow is well recognized to the skilled person in the art, therefore the detailed description thereof is not disclosed here.

The power consumption controller 70 has already saved information on electric devices 30, 40, 50, 60 connected to a power line of the house 100 and power sensor module 20, 20a together with ID numbers (for example, address information, product information) to distinguish those information, before the power management according to the present invention is carried out.

Furthermore, the management system for in-house power consumption can additionally comprise an indoor environment sensor and outdoor environment sensor to acquire environmental information inside and outside the house. The indoor environment sensor and outdoor environment sensor measures an environmental information inside and outside the house, for example a present temperature, humidity, dryness, and wind velocity and transmits indoor and outdoor environmental information to the power consumption controller 70. Then the power consumption controller 70 controls the whole or partial function of the in-house electric devices, which functions are closely related to environmental information (for example, air-conditioner 40, refrigerator, etc.), so that power consumption thereof is efficiently carried out.

In case that the in-house electric devices comprises an air conditioning device (that is, air conditioning function module) in particular, the power consumption of the electric devices can be decreased by controlling the function of the electric devices adequately according to the temperature inside or outside the house. For example, when it is necessary to weaken a cooling operation of an air-conditioner 40 or change it into a blowing operation due to a huge difference between inside temperature and outside temperature of the house, a controller of the power consumption 70 controls operation of the air-conditioner according to the environmental information reflecting, and then prevents the air-conditioner from over-operating and consuming electric power inefficiently.

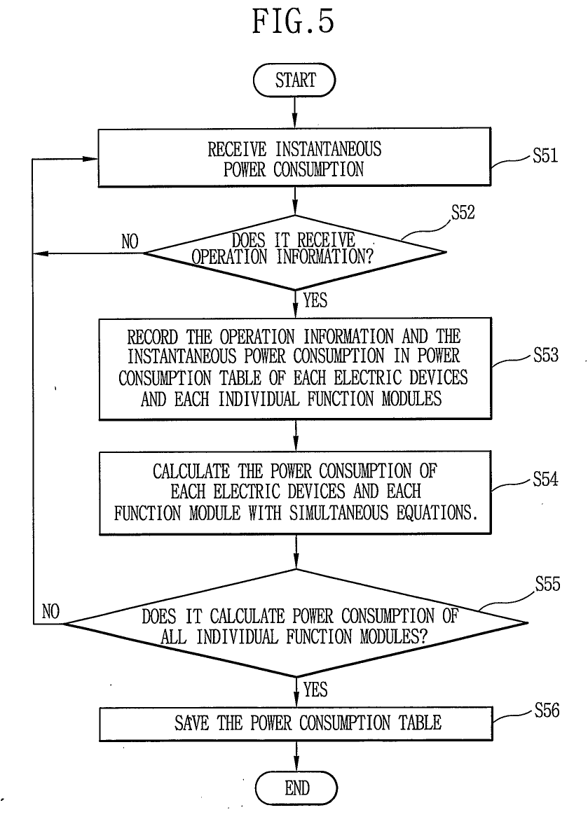

FIG. 5 is a flowchart to show a method to estimate power consumption of each in-house electric device, which is carried out in a management system for in-house power consumption according to the present invention.

More particularly, in step S51, a power consumption controller 70 receives instantaneous power consumption from a sensor module 20, 20a. At that time, the power consumption controller 70 waits for the instantaneous power consumption transmitted from a sensor module 20, 20a or more actively requests each power sensor module 20, 20a for current instantaneous power consumption to be received.

The power sensor module 20, 20a transmits instantaneous power consumption to the power consumption controller 70 when the change of the instantaneous power consumption exceeds a certain quantity of electric power and/or at specified time interval and/or when it is requested from the power consumption controller 70.

In step S52, the power consumption controller 70 receives operation information of a currently operating function (or the function module) from each in-house electric devices 30, 40, 50. If the power consumption controller 70 did not receive operation information, it waits till the operation information is received or it moves to a step S51 and receives an instantaneous power consumption. Otherwise, the power consumption controller 70 may actively request each in-house electric devices 30, 40, 50 for the current operation information and receives it.

In addition, the in-house electric devices 30, 40, 50 may transmit operation information when each operation is started or at specified time interval, or when there is a request of operation information from the power consumption controller 70 or there is a change in operation of a function module.

Such operation information should be directly corresponding to the received instantaneous power consumption, so that the power consumption controller 70 can carried out step S51 and S52 in an appropriate order.

In step S53 the power consumption controller 70 records the operation information and instantaneous power consumption in a predetermined power consumption table according to the operation information by each in-house electric devices 30, 40, 50, 60 and/or a function module. The recording is carried out by saving the information in a given storage means.

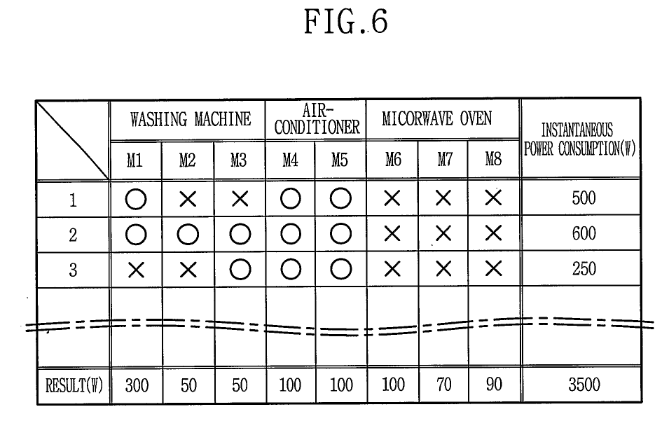

Detailed embodiment of the power consumption table is illustrated in FIG. 6. Shown in the figure, lateral axis shows each in-house electric devices (a washing machine, air-conditioner, microwave oven) and its function modules (M1, M2, M3), (M4, M5), (M6, M7, M8) and the longitudinal axis shows numbers of reception of the operation information, and an instantaneous power consumption (unit: watt, W) is shown at the rightmost column. For example, the first operation information is that a function module M1 of a washing machine and a function module M4, M5 of an air-conditioner work, and the instantaneous power consumption at the moment is 500 W.

In step S54, the power consumption controller 70 formulates certain simultaneous equations with multiple operation information and the corresponding instantaneous power consumption, and estimates power consumption for each in-house electric devices and/or individual function modules. In other words, as it formulates one simultaneous equation for one operation information and one instantaneous power consumption, it is possible to formulate simultaneous equations with individual function modules (M1-M8) and calculate a power consumption of each function module (M1-M8) with a certain calculation algorithm. For example, the first simultaneous equation is formulated: M1+M4+M5=500, the second simultaneous equation is formulated: M1+M2+M3+M4+M5=600.

With the simultaneous equations, it can be estimated the power consumption of individual function modules (M1-M8) and the result is displayed in the bottom line of a power consumption table in FIG. 6. Among these estimated function modules (M1-M8), the power consumption of each corresponding electric devices is calculated as a total amount of the power consumption of the related function modules (M1, M2, M3), (M4, M5), (M6, M7, M8).

Here, the power consumption controller 70 can estimate power consumption according to its own function module by the same method explained above. Therefore, the total instantaneous power consumption is consisted of power consumption of power consumption controller 70 and power consumption of the in-house electric devices 30, 40, 50 and 60. However, in order to explain focusing on the power consumption of the in-house electric devices 30, 40, 50 and 60 in the house, the power consumption of the power consumption controller 70 has not been explained. Even though the power consumption of power consumption controller 70 has not been described in the explanation of the whole instantaneous power consumption and accumulated power consumption in this specification, it is just for convenience of explanation and therefore it must be understood that it has been practically considered.

In step S55, the power consumption controller 70 determines whether it calculated power consumption of all in-house 100 electric devices and/or function modules connected to a power line, if not, it moves to a step S51. If so, it moves to step S56, and saves a power consumption table and finishes the procedure.

As explained above, the management system for in-house power consumption estimates power consumption of electric devices 30, 40, 50, 60 of the house 100 using power consumption of individual function modules M1-M8. As the power consumption controller 70 is saving and recognizing power consumption of individual function modules M1-M8, if it is found that the power consumption is bigger or smaller than a total power consumption of a currently operating function modules, the power consumption controller 70 determine that an overload is brought about in a function module of a certain electric devices or other trouble has been generated and provides a related message to a user. In addition, the power consumption controller 70 can find the function module overloaded or in trouble that consumes different amount of power from the saved power consumption using a simultaneous equation formulated by the method stated above and provide information about the function module to a user.

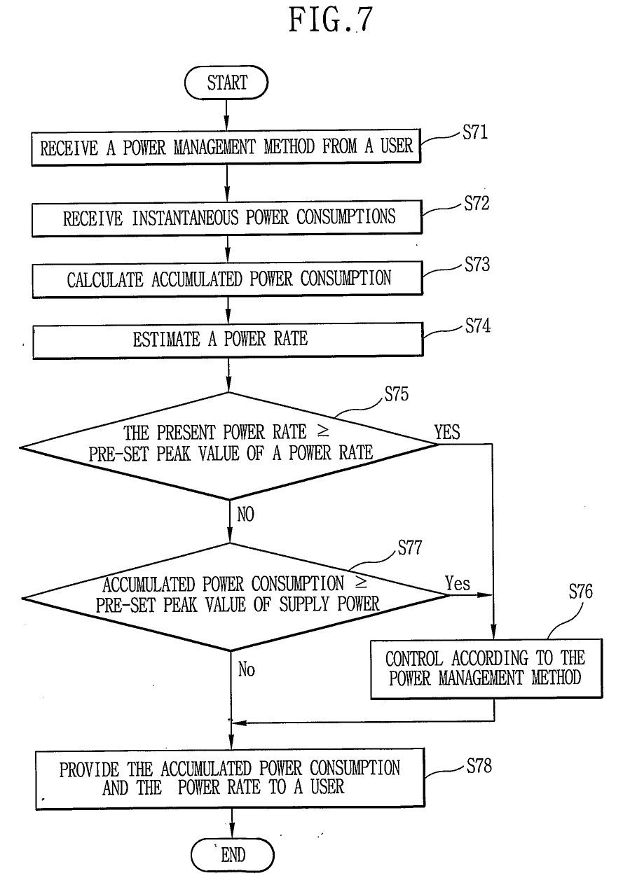

FIG. 7 is a flow chart of a power management method to be used in a management system for in-house power consumption according to the present invention.

More particularly, in step S71 the power consumption controller 70 is input with a management method of power consumption by a user. Such an input process is carried out with an input means placed in the power consumption controller 70, or an input means mounted on other electric devices and then the power consumption controller 70 receives the input power management method from the electric devices. In addition, if the power consumption controller 70 is not input with a power management method by a user and it has set with a power management method automatically, it can control according to the automatically set power management method or do not carry out a separate control operation.

The power management method may be the first most appropriate usage method of use to set a peak value of a power rate and to manage the electric devices to be operated so that the present power rate is placed below the peak value, for example, or the second most appropriate usage method that is to set a certain peak value of supply power and adjust the accumulated power consumption of the electric devices for a certain time of period to be placed below the peak value.

More particularly, as the first method, a power consumption controller 70 controls each electric devices 30, 40, 50, 60 by the first most appropriate usage method, (for example, the power consumption controller 70 is to carry out a cooling cycle according to each function module, only when indoor temperature is more than 28° C. and operates blowing cycle when the temperature is 28° C. or less, or make use of the electric devices during the time when the power rate is relatively low).

In addition, as the second method, the power consumption controller 70 stops the whole operation of electric devices 30, 40, 50, 60 or a part of the operation (that is, a function module) so as to regulate an instantaneous power consumption of each electric devices 30, 40, 50, 60. For example, the power consumption controller 70 stops the operation of a fan motor of indoor unit 43 of an air-conditioner 40 by raising an operation temperature of a cooling cycle of the air-conditioner 40 or stops the operation of a boiler by dropping the operation temperature or stops the operation of a television. But the priority to stop the operations is decided according to safety reason for a user or a system. For example, the priority of a refrigerator that must be maintained at certain temperature is low and that of an electric iron which use can be postponed is high, and the priority of surveillance system of the house 100 which should be always running is much lower, the power consumption controller 70 stops the whole function or partial function of electric devices in order of the priority.

The first and the second most appropriate usage method are preferred examples of the power management method, and both methods can be carried out together. Furthermore, the power management methods can only provide a current electric rate and/or accumulated power consumption or a list of the currently operating electric devices to a user so that the user may control a certain operation.

The power consumption controller 70 receives instantaneous power consumption from a sensor module 20, 20a in step S72, and estimates accumulated power consumption for a certain period of time in step S73. The certain period of time generally means the duration from a date after relevant date of billing to date, however, it may be a certain period of time which was decided by a user (for example three days or one week).

The power consumption controller 70 estimates the electric power rate that has been charged to date with accumulated power consumption in step S74.

To estimates the power rate, the power consumption controller 70 can save a certain algorithm to calculate a power rate with accumulated power consumption, or it is possible that the power consumption controller 70 accesses to a server of an electric power supply company via an outside network and transmit accumulated power consumption to the server and receive the power rate estimated by the server. The power rate can be a fixed power rate, or it may be an estimated power rate.

In step S75, the power consumption controller 70 compares a present power rate with a pre-set peak value of a power rate. If the present power rate is as same as the pre-set peak value or higher, it moves to step S76, and if not, it moves to step S77.

In step S76, the power consumption controller 70 controls electric devices 30, 40, 50 and 60 by means of the stored power management method.

In step S77, the power consumption controller 70 compares accumulated power consumption with pre-set peak value of supply power. If the accumulated power consumption is as same as the pre-set peak value or higher, it moves to step S76 and control it according to the power management method and if not, it moves to step S78.

In step S78, the power consumption controller 70 provides current accumulated power consumption and/or an electric power rate to the user.

The steps S75, S77 stated above, the order of them may be changed each other, and it is possible to carry out only one step by the choice of the user.

The present invention having such a composition can estimate power consumption of each-electric devices and/or power consumption according to individual function modules of the electric devices.

The present invention can further provide various methods for electric power control to a user according to operation information and power consumption of each electric device or by a power rate.

The present invention can control electric devices with a power management method automatically set or set by a user based on operation information and power consumption of electric devices or a power rate.

The present invention can further control operation of electric devices by means of inside and outside environment of the house and carry out efficient power consumption.

The present invention can further control each electric device according to its individual function module so that efficient power consumption control can be realized.

The present invention can identify the state of electric devices and/or its individual function module with the power consumption of each electric devices and/or the power consumption according to its individual function module.

What is claimed is:

1. A management system for in-house power consumption comprising:
at least one or more electric devices which comprise a communication means and transmit current operation information via the communication means on a given network; an power sensor module that measures an instantaneous power consumption of the total electric devices and transmit it on the network; and a power consumption controller that saves a previously received the operation information and the instantaneous power consumption and estimates the power consumption of each electric device on the basis of the saved operation information and instantaneous power consumption and the currently received operation information and instantaneous power consumption.

2. A management system for in-house power consumption of claim 1, wherein, the operation information includes currently operating individual function modules of the electric devices.

3. A management system for in-house power consumption of claim 1, wherein, the electric devices transmit the operation information to the power consumption controller whenever there is a change of its operation.

4. A management system for in-house power consumption of claim 1 or 2, wherein, the power consumption controller estimates power consumption of each of the currently operating individual function modules of the electric devices and then estimates the power consumption of the electric devices according to the estimated power consumption of the individual function modules.

5. A management system for in-house power consumption of claim 4, wherein, the power consumption controller provides a user with at least of one or more information among the operation information, power consumption of the electric devices and power consumption of each function module of the electric devices.

6. A management system for in-house power consumption of claim 1, wherein, the system further comprises an electric device which does not comprise a communication means and the second power sensor module which is connected between the electric device and the network and transmits the instantaneous power consumption of the electric devices to the power consumption controller.

7. A management system for in-house power consumption of claim 1 or 6, wherein, the power sensor module is consisted of an power measuring means that measures the instantaneous power consumption and a transmission means that transmits the measured instantaneous power consumption to the power consumption controller.

8. A management system for in-house power consumption of claim 1 or 2, wherein, the power consumption controller estimates a power rate based on accumulated consumption of the electric devices for the certain period of time and provide it to a user.

9. A management system for in-house power consumption of claim 8, wherein, the power consumption controller provides the user with the most appropriate method for utilizing the electric devices based on the estimated power rate.

10. A management system for in-house power consumption of claim 9, wherein, the most appropriate method for utilizing the electric devices comprises a method of use of individual function module of the electric devices.

11. A management system for in-house power consumption of claim 9, wherein, the most appropriate method for utilizing the electric devices includes the operating time of the electric devices.

12. A management system for in-house power consumption of claim 1 or 2, wherein, the system further comprises an indoor environment sensor and outdoor environment sensor to collect environmental information of an place where the sensors are installed and the power consumption controller individually control the electric devices according to the environmental information received from the indoor environment sensor and outdoor environment sensor.

13. A management system for in-house power consumption of claim 12, wherein, the power consumption controller controls air-conditioning function module not to be over-operated among the function modules of the electric devices.

14. A management system for in-house power consumption comprising:
at least one or more electric devices which comprise a communication means and transmits current operation information via the communication means on a given network; an power sensor module that measures an instantaneous power consumption of the total electric devices and transmits it through the network, and a power consumption controller that receives the operation information and the instantaneous power consumption and estimates accumulated power consumption of electric devices for a certain period of time and provides a user with the accumulated power consumption and the operation information of the electric devices.

15. A management system for in-house power consumption of claim 14, wherein, the power consumption controller performs a power management method when the accumulated power consumption is higher than the predetermined peak value of supply power.

16. A management system for in-house power consumption of claim 15, wherein, the power consumption controller stops the whole function or a part of the function of the electric devices by the power management method.

17. A management system for in-house power consumption of claim 16, wherein, the power consumption controller stops the whole function or a part of the function of the electric devices according to a predetermined priority in performing the power management method.

18. A management system for in-house power consumption as of claim 14, 15, 16 and 17, wherein, the operation information includes currently operating individual function modules of the electric devices.

19. A management system for in-house power consumption of claim 18, wherein, the power consumption controller stops individual function module of the electric devices.

20. A management system for in-house power consumption of claim 14, wherein, the power consumption controller estimates a power rate with the accumulated power consumption.

21. A management system for in-house power consumption of claim 20, wherein, the power consumption controller provides a message of restriction of use of the electric devices to the user when the power rate is more than the predetermined peak value of a power rate.
